(19) United States
(12) Patent Application Publication
(10) Pub. No.: US 2021/0104594 A1
(43) Pub. Date: Apr. 8, 2021

(54) DISPLAY PANEL, PREPARATION METHOD THEREOF AND DISPLAY DEVICE

(71) Applicants: CHENGDU BOE OPTOELECTRONICS TECHNOLOGY CO., LTD., CHENGDU, SICHUAN (CN); BOE TECHNOLOGY GROUP CO., LTD., BEIJING (CN)

(72) Inventors: Xiaoxia LIU, BEIJING (CN); Fei LI, BEIJING (CN); Fuzheng XIE, BEIJING (CN); Junhui YANG, BEIJING (CN); Jiaxiang ZHANG, BEIJING (CN); Kang WANG, BEIJING (CN)

(73) Assignees: CHENGDU BOE OPTOELECTRONICS TECHNOLOGY CO., LTD., CHENGDU, SICHUAN (CN); BOE TECHNOLOGY GROUP CO., LTD., BEIJING (CN)

(21) Appl. No.: 16/959,228

(22) PCT Filed: Feb. 5, 2020
(86) PCT No.: PCT/CN2020/074315

§ 371 Date: Jun. 30, 2020

(30) Foreign Application Priority Data
Feb. 18, 2019 (CN) 201910120314.8

(51) Int. Cl. H01L 27/32; H01L 23/00; H01L 51/56

(52) U.S. Cl. CPC H01L 27/3276; H01L 24/05; H01L 51/0097; H01L 51/56; H01L 2224/0557; H01L 24/03

(57) ABSTRACT

The invention relates to a display panel, a preparation method thereof and a display device. The display panel comprises: a substrate comprising a display area and a non-display area at least positioned on one side of the display area, one or more via holes are formed in the non-display area; a circuit layer positioned on one side of the substrate and comprising a plurality of traces which extend from the display area of the substrate to the non-display area; and bonding pads positioned on one side of the substrate away from the circuit layer, an orthographic projection of the bonding pads on the substrate covers an orthographic projection of the one or more via holes on the substrate, and the circuit layer is connected with the bonding pads through the one or more via holes.

### CROSS-REFERENCE TO RELATED APPLICATIONS

This application is a U.S. National Stage under 35 U.S.C. § 371 of International Application No. PCT/CN2020/074315, as filed on Feb. 5, 2020, which claims a priority of a Chinese patent application No. 201910120314.8 that was filed on Feb. 18, 2019, and the contents disclosed in any of these applications are incorporated herein by reference in its entirety.

### TECHNICAL FIELD

The present disclosure a display panel, a preparation method thereof and a display device.

### BACKGROUND

At present, a full screen display becomes the trend of electronic products, particularly smart phone products, and both display-component manufacturers and display manufacturers strive to increase screen-to-body ratio. At present, the mainstream scheme adopted by the full-screen display is a PAD bonding scheme, that is, a flexible substrate and/or a flexible circuit board (FCB) bent at the outer side of a substrate is used to connect a circuit on one side of the substrate with a circuit on the other side of the substrate. Because the flexible circuit board is folded to the other side of the substrate, the width of the frame of the substrate can be reduced to the distance between the bonding pads and the bending part of the flexible circuit board.

### SUMMARY

The present invention provides the following technical solutions.

A display panel, comprising:

a substrate comprising a display area and a non-display area at least positioned on one side of the display area, one or more via holes are formed in the non-display area;

a circuit layer positioned on one side of the substrate and comprising a plurality of traces which extend from the display area to the non-display area;

bonding pads positioned on one side of the substrate away from the circuit layer, an orthographic projection of the bonding pads on the substrate covers an orthographic projection of the one or more via holes on the substrate, and the circuit layer is connected with the bonding pads through the one or more via holes.

Alternatively, the number of the one or more via holes is plural, the plurality of traces is in one-to-one correspondence with the plurality of via holes, and each trace is connected to the bonding pad through the via hole corresponding to the trace.

Alternatively, the number of the one or more via holes is plural and less than the number of traces, each via hole corresponds to one or more traces, and each trace is connected to the bonding pad through a corresponding via hole.

Alternatively, the plurality of via holes extend in a direction parallel to an edge of the display area.

Alternatively, the plurality of traces comprises a plurality of data lines.

Alternatively, the non-display area is provided around the display area.

Alternatively, the display panel further comprises:

a circuit assembly located on one side of the bonding pad away from the substrate and bound to the bonding pad.

Alternatively, the circuit assembly comprises one or more of an integrated circuit, a circuit board, a flexible circuit board, a chip on film.

Alternatively, the substrate is a flexible substrate; and

the display panel further comprises a protective layer arranged on the side of the substrate away from the circuit layer, and the protective layer is provided with a notch which avoids the bonding pad.

Alternatively, an orthographic projection of the protective layer on the substrate does not cover an orthographic projection of the bonding pads on the substrate.

A display device comprising the above display panel.

A method of manufacturing a display panel, comprising:

providing one or more via holes in a non-display area of a substrate;

providing a circuit layer on one side of the substrate, wherein the circuit layer comprises a plurality of traces which extend from a display area of the substrate to the non-display area of the substrate; and

providing bonding pads on one side of the substrate away from the circuit layer, an orthographic projection of the bonding pads on the substrate covers an orthographic projection of the one or more via holes on the substrate, and the circuit layer is connected with the bonding pads through the one or more via holes.

Alternatively, the substrate is a flexible substrate; and

before providing bonding pads on one side of the substrate away from the circuit layer, the method further comprises:

providing a protective layer on one side of the substrate from the circuit layer, and the protective layer is provided with a notch which avoids the bonding pads.

Alternatively, after providing a protective layer on one side of the substrate from the circuit layer, the method further comprises:

providing a circuit assembly on one side of the protective layer away from the substrate.

### BRIEF DESCRIPTION OF THE DRAWINGS

FIG. 1 is a schematic diagram of a side of the display panel according to an embodiment of the present invention;

FIG. 2 is a schematic cross-sectional view illustrating a frame region of the display panel according to an embodiment of the present invention;

FIG. 3 is a schematic diagram illustrating a structure of a frame region on one side of the display panel according to an embodiment of the present invention;

FIG. 4 is a schematic diagram illustrating a structure of a frame region on one side of the display panel according to an embodiment of the present invention;

FIG. 5 is a schematic diagram illustrating a structure of a frame region on one side of the display panel according to an embodiment of the present invention;

FIG. 6 is a flowchart illustrating a method for fabricating the display panel according to an embodiment of the present invention; and

FIG. 7 is a flowchart of a method for manufacturing the display panel according to an embodiment of the invention.

### DETAILED DESCRIPTION

The technical solutions in the embodiments of the present invention will be clearly and completely described below with reference to the accompanying drawings, and it is to be understood that the described embodiments are only parts of the embodiments of the present invention, and not all of the embodiments. All the other embodiments, which can be obtained by a person skilled in the art without making any creative effort based on the embodiments in the present invention, belong to the protection scope of the present invention.

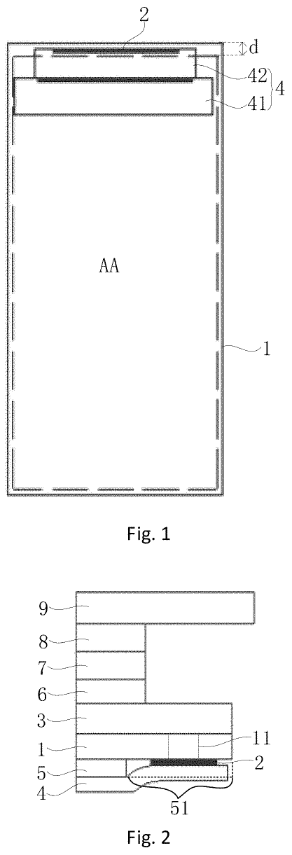

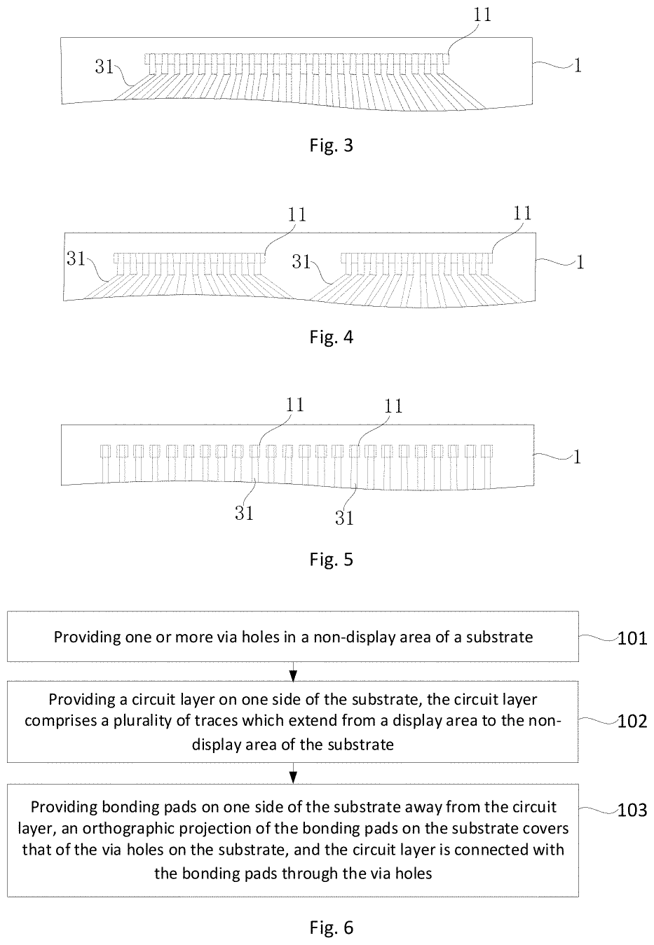

As shown in FIGS. 1 to 5, an embodiment of the present invention provides a display panel. The display panel comprises a substrate 1, the substrate 1 comprising a display area and a non-display area at least at one side of said display area. In FIG. 1, the display area of the substrate 1 is shown as an AA area surrounded by a dotted line, and the non-display area is shown on an upper side of the display area. FIG. 2 is a schematic cross-sectional view illustrating a frame region of the display panel according to an embodiment of the invention. As shown in FIG. 2, the display panel further includes a circuit layer 3 on one side of the substrate 1. FIG. 3 is a schematic structural diagram of the frame region on one side of the display panel according to an embodiment of the invention. As shown in FIG. 3, the circuit layer includes a plurality of traces 31 extending from the display area to the non-display area. In addition, as shown in FIGS. 2 and 3, one ore more via holes 11 are provided in the non-display area of the substrate 1. As can be appreciated by a person skilled in the art, the one or more via holes 11 pass through the substrate 1. Furthermore, as shown in FIG. 2, the display panel includes bonding pads 2 located on a side of the substrate 1 away from the circuit layer, and an orthogonal projection of the bonding pads 2 on the substrate 1 covers an orthogonal projection of the one or more via holes 11 on the substrate 1. As shown in FIGS. 2 and 3, the circuit layer 3 is connected to the bonding pads 2 through the via holes 11.

In the display panel, the bonding pads 2 and the circuit layer 3 are respectively disposed on two sides of the substrate 1, the substrate 1 is provided with the via holes 11, and the traces 31 of the circuit layer 3 on one side of the substrate 1 is connected to the bonding pads 2 on the other side of the substrate 1 through the one or more via holes 11. Thus, the display panel can realize a narrow bezel.

Specifically, the display panel of the invention does not need a flexible bending part, and since a bending area is removed, the frame can be designed to be narrower. For example, in the bending scheme of the related art, a circuit on one side of the substrate is bound to the bonding pads on the other side through a bent flexible wiring board. However, although the frame width is reduced to some extent, the frame width of the display panel also includes a region for bending, and thus the extent of frame reduction of this solution in the related art is limited. On the contrary, as shown in FIG. 1, because the bending portion outside the frame is omitted, the frame width d of the display panel of the present invention is substantially smaller than that of the display panel in the bending scheme of the related art.

In addition, in the bending scheme of the related art, the manufacturing process is also complicated due to the addition of the bending process. On the contrary, the display panel of the present invention does not need a bending process, and only the via hole 11 is formed on the substrate 1, so the manufacturing process is also simpler. In addition, the front surface of the cell does not need to be provided with connecting areas for the bonding pads and the flexible bending part, so that the layout ratio of the display panel cell is higher.

In a specific embodiment, in the display panel of the present invention, the non-display area is disposed around the display area AA on one side of the substrate 1. It will be appreciated by those skilled in the art that the non-display area may be located at least on one side of the display area AA. Further, the via hole 11 extends in a direction parallel to the edge of the display area.

As shown in FIGS. 3 and 4, in a specific embodiment of the present disclosure, a plurality of via holes 11 is disposed on the substrate 1, and the number of via holes 11 is less than the number of traces 31. Therefore, each via hole 11 corresponds to one or more traces 31, and each trace 31 is connected to the bonding pad 2 through the corresponding via hole 11.

The plurality of traces 31 may be prepared by a patterning process, and for example, the specific steps may include: depositing a metal layer covering the via holes 11 on the substrate 1; forming the patent of the plurality of traces 31 by a patterning process, so that the plurality of traces 31 are not in contact with each other, and each trace 31 includes a connection portion filled in the via hole 11 for connecting with the bonding pads 2. Specifically, the circuit layer 3 may further include a thin film transistor (TFT) array layer, and the plurality of traces 31 may specifically include a plurality of data lines, for example, gate signal lines and/or data signal lines of the TFT array.

Illustratively, as shown in FIG. 3, when there is only one via hole 11 on the substrate 1, the via hole 11 corresponds to all the traces 31. Specifically, the via hole 11 may have a bar shape and extend along an edge of the display area. Further, each trace 31 may be arranged along the extending direction of the via hole 11 to facilitate the patterning of the trace 31.

Illustratively, when there are several via holes 11 on the substrate 1, each via hole 11 may correspond to several traces 31. As shown in FIG. 4, taking two via holes as example, each via hole 11 has a bar shape, and two via holes 11 extend along the edge of the display area and are adjacent to each other. At this time, the traces 31 may be divided into two groups, which correspond to the two via holes 11 respectively. In this case, each group of traces 31 is disposed adjacently, and each group of traces 31 is connected to the bonding pads 2 through a corresponding one of the via holes 11. The way of connecting through more than two via holes 11 can reduce the risk of short circuit between the traces 31.

As shown in FIG. 5, in a specific embodiment, the substrate 1 has a plurality of via holes 11 corresponding to a plurality of traces 31 in one-to-one correspondence, and each trace 31 is connected to the bonding pad 2 through one via hole 11 corresponding to the trace 31. By adopting the one-to-one correspondence of the via holes 11 and the traces 31, each trace 31 can be connected with the bonding pad 2 through one single via hole 11, which can effectively avoid the risk of short circuit between the traces 31. For example, a plurality of via holes 11 may be sequentially arranged along the edge of the display area to facilitate the patterning of the traces 31.

As shown in FIGS. 1 and 2, the display panel provided by the embodiment of the invention may further include a circuit assembly 4 disposed on a side of the bonding pads 2 away from the substrate 1, and the circuit assembly 4 is bonded to the bonding pads 2. Bonding refers to a connection that forms an electrical connection between two components by soldering, coupling, adhering, and the like.

Illustratively, the circuit assembly 4 may include one or more of an integrated circuit (IC), a circuit board (PCB), a flexible printed circuit (FPC), and a chip on film (COF).

In a specific embodiment, the substrate 1 may be a flexible material, such as polyimide. Compared with a glass substrate, the flexible substrate is thinner and is easier to manufacture via holes.

Illustratively, the via hole may be prepared on the substrate by a patterning process. Specifically, the “patterning process” or “patterning” described in the embodiments of the present invention is a process of preparing a structure pattern by using one or more steps of gluing, exposing, etching, and developing.

As shown in FIG. 2, the display panel may further include a protective layer 5 disposed on the side of the substrate 1 away from the circuit layer 3. The protective layer 5 is provided with a notch 51 avoiding the bonding pads 2. In other words, the orthographic projection of protective layer 5 on substrate 1 does not cover the orthographic projection of bonding pads 2 on the substrate. That is, there is no protective layer 5 at the location of the bonding pads 2, thereby allowing the bonding of the bonding pads 2 with the circuit assembly 4 on the side of the protective layer 5 away from the substrate 1. Illustratively, as shown in FIG. 2, the bonding pads 2 are disposed on the substrate 1 at the notch 51 of the protective layer 5.

As shown in FIG. 1, the circuit assembly 4 includes a main circuit board (MFPC) 41 and a chip on film (COF) 42. The MFPC 41 is disposed on the side of the protective layer 5 away from the substrate 1, and is bound to the bonding pads 2 through the COF 42.

The display panel in the embodiment of the present invention may be a flexible display panel. However, the embodiments are only examples of the preferred embodiment of the present invention, and does not constitutes any limitation. In practical applications, the display panel of the present invention may also be a rigid display panel, and the substrate thereof may also be a glass material.

As shown in FIG. 2, in a specific embodiment, the display panel provided by the present invention may further include an OLED display unit 6, a touch device 7 and a polarizer 8 sequentially disposed on a side of the substrate 1 away from the circuit device.

Further, the embodiment of the present invention may further include a cover plate 9 or an encapsulation layer disposed on a side of the substrate 1 away from the circuit assembly.

For example, when the cover plate 9 is used for packaging, the touch device 7, the polarizer 8 and the cover plate 9 may be sequentially attached to the substrate. Alternatively, the touch device 7 and the polarizer 8 may be disposed on the cover plate 9, and then the cover plate 9 and the substrate are bonded together by using a transparent adhesive (OCA).

The embodiment of the invention also provides a display device which comprises the display panel in any one of the above embodiments. The display device has a narrow display frame, and can realize full-screen display.

Specifically, the display device can be applied to any product or component with a display function, such as a mobile phone, a tablet computer, a television, a display, a notebook computer, a digital photo frame, a navigator and the like. Since the principle of solving the problem of the display device is similar to that of the display panel, the applications of the display device can be referred to the applications of the display panel, and the descriptions are omitted.

Based on the display panel, the embodiment of the invention also provides a preparation method of the display panel. As shown in FIG. 6, the method comprises the steps of:

Step 101, providing one or more via holes in a non-display area of a substrate;

Step 102, providing a circuit layer on one side of the substrate, wherein the circuit layer comprises a plurality of traces which extend from a display area of the substrate to the non-display area of the substrate; and

Step 103, providing bonding pads on one side of the substrate away from the circuit layer, an orthographic projection of the bonding pads on the substrate covers an orthographic projection of the one or more via holes on the substrate, and the circuit layer is connected with the bonding pads through the one or more via holes.

In the display panel obtained by the above preparation method, as shown in FIGS. 1 and 2, the bonding pads 2 and the circuit layer 3 are respectively disposed on two sides of the substrate 1, the substrate 1 is provided with the via holes 11, and the traces 31 of the circuit layer 3 on one side of the substrate 1 is connected to the bonding pads 2 on the other side of the substrate 1 through the via holes 11. Thus, the display panel can realize a narrow bezel. Moreover, the display panel does not need a flexible bending part, so that a bending area is saved, and therefore, the frame can be designed to be narrower. Thus, the frame width d in FIG. 1 is obviously smaller than the frame width in a bending process of the related art. Moreover, compared with the display panel of the related art, the display panel of this embodiment does not need a bending process, and only the via holes 11 is prepared on the substrate 1, so that the preparation process is simpler. In addition, the front surface of the cell does not need to be provided with connecting areas for the bonding pads and the flexible bending part, so that the layout ratio of the cell is higher.

In a specific embodiment, the trace can be fabricated in one step in step 102, or can be fabricated in two steps. Illustratively, when the manufacturing is performed in two steps, the first step is to form a pattern of the traces before providing the via holes on the substrate (before step 101), and the second step is to fill the via holes with a conductive material after providing the via holes on the substrate (after step 101), and form a connection portion of each trace in the via holes by an etching process.

In a specific embodiment, the substrate may be a flexible material, such as polyimide. Compared with a glass substrate, the flexible substrate is thinner and is easier to manufacture via holes.

Further, before step 103, that is, before providing bonding pads on one side of the substrate away from the circuit layer, the preparation method provided by the embodiment of the present invention may further include the following steps: providing a protective layer on one side of the substrate from the circuit layer 3, and the protective layer is provided with a notch which avoids the bonding pads. Illustratively, as shown in FIG. 2, the bonding pads 2 are disposed on the substrate 1 at the notch 51 of the protective layer 5.

Further, after providing a protective layer on one side of the substrate from the circuit layer 3, the method further comprises the following steps: providing a circuit assembly on one side of the protective layer away from the substrate 1. Illustratively, as shown in FIG. 1, the circuit assembly 4 includes a main circuit board (MFPC) 41 and a chip on film (COF) 42. The MFPC 41 is disposed on a side of the protection layer 5 away from the substrate 1, and is bonded to the bonding pads 2 through the COF 42.

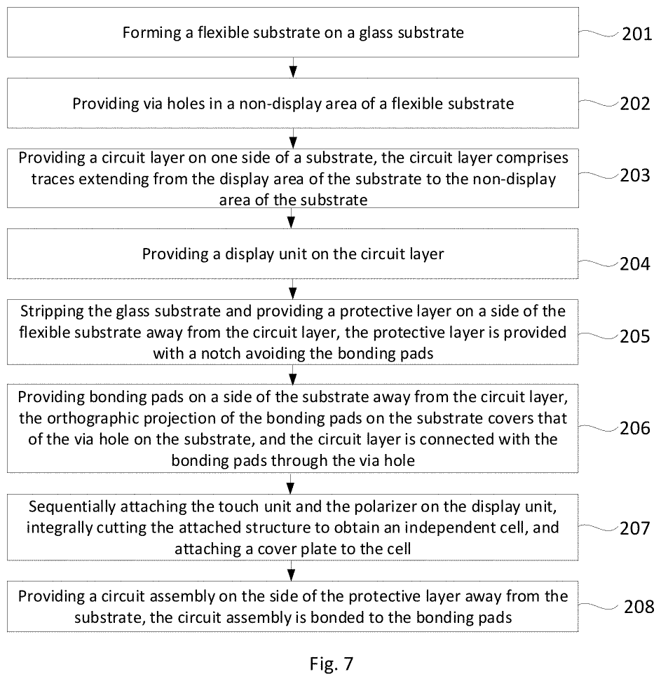

Specifically, the following description takes a flexible OLED display panel as an example, and illustrates a method for manufacturing the display panel of the embodiment of the present invention. As shown in FIG. 7, the process of the method includes:

Step 201, forming a flexible substrate on a glass substrate;

Step 202, providing one or more via holes in a non-display area of a flexible substrate;

Step 203, providing a circuit layer on one side of a substrate, wherein the circuit layer comprises a plurality of traces which extend from the display area to the non-display area of the substrate;

Step 204, providing a display unit on the circuit layer, wherein the display unit can comprise an anode, a light-emitting layer, a cathode and other structures which are sequentially stacked;

Step 205, stripping the glass substrate, and providing a protective layer on one side of the flexible substrate away from the circuit layer, wherein the protective layer is provided with a notch avoiding the area of the bonding pads;

Step 206, providing bonding pads on one side of the substrate away from the circuit layer, wherein the orthographic projection of the bonding pads on the substrate covers the orthographic projection of the via hole on the substrate, and the circuit layer is connected with the bonding pads through the via hole;

Step 207, sequentially attaching the touch unit and the polarizer on the display unit, integrally cutting the attached structure to obtain an independent cell, and attaching a cover plate to the cell; and

Step 208, providing a circuit assembly on the side of the protective layer away from the substrate, wherein the circuit assembly is bonded to the bonding pads.

Illustratively, the circuit layer may further include a TFT array, and the plurality of traces may specifically include data lines, such as gate signal lines and/or data signal lines.

The flow of the above method steps of the embodiments of the invention is exemplary and the order in which the various steps are performed may be varied as desired. For example, the order of execution of the various steps may be modified, or two or more steps may be performed in parallel.

It will be apparent to those skilled in the art that various changes and modifications may be made in the embodiments of the invention without departing from the spirit and scope of the invention. Thus, if such modifications and variations of the present invention fall within the scope of the claims of the present invention and their equivalents, they are also intended to include in the present invention.

1. A display panel, comprising:
a substrate comprising a display area and a non-display area at least positioned on one side of the display area, one or more via holes are formed in the non-display area;
a circuit layer positioned on one side of the substrate and comprising a plurality of traces which extend from the display area to the non-display area; and
bonding pads positioned on one side of the substrate away from the circuit layer, an orthographic projection of the bonding pads on the substrate covers an orthographic projection of the one or more via holes on the substrate, and the circuit layer is connected with the bonding pads through the one or more via holes.

2. The display panel of claim 1, wherein the number of the one or more via holes is plural, the plurality of traces is in one-to-one correspondence with the plurality of via holes, and each trace is connected to the bonding pad through the via hole corresponding to the trace.

3. The display panel of claim 1, wherein the number of the one or more via holes is plural and less than the number of traces, each via hole corresponds to one or more traces, and each trace is connected to the bonding pad through a corresponding via hole.

4. The display panel of claim 2, wherein the plurality of via holes extend in a direction parallel to an edge of the display area.

5. The display panel of claim 1, wherein the plurality of traces comprises a plurality of data lines.

6. The display panel of claim 1, wherein the non-display area is provided around the display area.

7. The display panel of claim 1, further comprising:
a circuit assembly located on one side of the bonding pad away from the substrate and bound to the bonding pad.

8. The display panel of claim 7, wherein the circuit assembly comprises one or more of an integrated circuit, a circuit board, a flexible circuit board, a chip on film.

9. The display panel of claim 1, wherein the substrate is a flexible substrate; and
the display panel further comprises a protective layer arranged on the side of the substrate away from the circuit layer, and the protective layer is provided with a notch which avoids the bonding pad.

10. The display panel of claim 9, wherein an orthographic projection of the protective layer on the substrate does not cover an orthographic projection of the bonding pads on the substrate.

11. A display device comprising a display panel comprising:
a substrate comprising a display area and a non-display area at least positioned on one side of the display area, one or more via holes are formed in the non-display area;
a circuit layer positioned on one side of the substrate and comprising a plurality of traces which extend from the display area to the non-display area; and
bonding pads positioned on one side of the substrate away from the circuit layer, an orthographic projection of the bonding pads on the substrate covers an orthographic projection of the one or more via holes on the substrate, and the circuit layer is connected with the bonding pads through the one or more via holes.

12. A method of manufacturing a display panel, comprising:
providing one or more via holes in a non-display area of a substrate;
providing a circuit layer on one side of the substrate, wherein the circuit layer comprises a plurality of traces which extend from a display area of the substrate to the non-display area of the substrate; and
providing bonding pads on one side of the substrate away from the circuit layer, an orthographic projection of the bonding pads on the substrate covers an orthographic projection of the one or more via holes on the substrate, and the circuit layer is connected with the bonding pads through the one or more via holes.

13. The method of claim 12, wherein the substrate is a flexible substrate; and
before providing bonding pads on one side of the substrate away from the circuit layer, the method further comprises:
providing a protective layer on one side of the substrate from the circuit layer, and the protective layer is provided with a notch which avoids the bonding pads.

14. The method of claim 13, wherein after providing a protective layer on one side of the substrate from the circuit layer, the method further comprises:
providing a circuit assembly on one side of the protective layer away from the substrate.

15. The display device of claim 11, wherein the number of the one or more via holes is plural, the plurality of traces is in one-to-one correspondence with the plurality of via holes, and each trace is connected to the bonding pad through the via hole corresponding to the trace.

16. The display device of claim 11, wherein the number of the one or more via holes is plural and less than the number of traces, each via hole corresponds to one or more traces, and each trace is connected to the bonding pad through a corresponding via hole.

17. The display device of claim 15, wherein the plurality of via holes extend in a direction parallel to an edge of the display area.

18. The display device of claim 11, wherein the plurality of traces comprises a plurality of data lines.

19. The display device of claim 11, wherein the substrate is a flexible substrate; and
the display panel further comprises a protective layer arranged on the side of the substrate away from the circuit layer, and the protective layer is provided with a notch which avoids the bonding pad.

20. The display device of claim 19, wherein an orthographic projection of the protective layer on the substrate does not cover an orthographic projection of the bonding pads on the substrate.
